(19) United States
(12) Patent Application Publication
(10) Pub. No.: US 2012/0247539 A1
(43) Pub. Date: Oct. 4, 2012

(54) Rear-Contact Heterojunction Photovoltaic Cell

(75) Inventor: Pére Roca i Cabarrocas, Villebon Sur Yvette (FR)

(73) Assignees: TOTAL SA, Courbevoie (FR); ECOLE POLYTECHNIQUE, Palaiseau (FR); CENTRE NATIONAL DE LA RECHERCHE SCIENTIFIQUE, Paris Cedex 16 (FR)

(21) Appl. No.: 13/515,657

(22) PCT Filed: Dec. 10, 2010
(86) PCT No.: PCT/IB10/55725

§ 371 Date: Jun. 13, 2012

(30) Foreign Application Priority Data
Dec. 14, 2009 (FR) 09/58922

(51) Int. Cl. H01L 31/0747; H01L 31/20; H01L 31/0224; H01L 31/042

(52) U.S. Cl. 136/249; 136/258; 438/96; 136/256; 257/E31.047

(57) ABSTRACT

The invention relates to a semiconductor device comprising: a crystalline semiconductor substrate (1) having a front face (1a) and a rear face (1b); a front passivation layer (3) placed on the front face (1a) of the substrate (1); a rear passivation layer (2) placed on the rear face (1b) of the substrate (1); a first metallization zone (10) placed on the rear passivation layer (2) and designed for collecting electrons; a second metallization zone designed for collecting holes, comprising: a surface portion (11) placed on the rear passivation layer (2); and an internal portion (12) passing through the rear passivation layer (2) and forming, in the substrate (1), a region in which the concentration of electron acceptors is greater than the rest of the substrate (1). The invention also relates to a module of photovoltaic cells using this device and to a process for manufacturing this device.

### FIELD OF THE INVENTION

The present invention relates to a back-contact hetero-junction photovoltaic cell and also to the process for manufacturing same.

### TECHNICAL BACKGROUND

As is known per se, a photovoltaic module comprises a plurality of photovoltaic cells (or solar cells) connected in series and/or in parallel. A photovoltaic cell is a semiconductor diode designed to absorb light energy and convert it into electrical energy. This semiconductor diode comprises a p-n junction between two layers of respectively p-doped and n-doped silicon. During the formation of the junction, a potential difference (and therefore a local electric field) appears, due to the excess of free electrons in the n layer and due to the shortage of free electrons in the p layer.

When photons are absorbed by the semiconductor, they give up their energy in order to produce free electrons and holes. Given the potential difference that exists at the junction, the free electrons have a tendency to accumulate in the n zone and the holes to accumulate in the p zone. Collecting electrodes in contact respectively with the n zone and the p zone make it possible to recover the current emitted by the photovoltaic cell.

Solar cells based on monocrystalline or polycrystalline silicon are conventionally developed by putting the positive and negative contacts on each of the faces of the cell. The back face is generally completely covered with metal since only the conductivity counts (no light having to pass through the back face), whereas the front face, that is to say the one which is illuminated, is contacted by a metal grid which allows most of the incident light to pass through.

Recently, it has been proposed to place the electrical contacts only on the back face (rear-contacted cells). This implies producing selective contacts on a single face. The advantage of this technique is not having any shading on the front face while making it possible to reduce the ohmic losses due to the metal contacts since they cover a much larger surface of the cell. Added to this is the fact that it is not necessary to use a transparent conductive oxide on the front face (no electrical conduction is necessary) but rather amorphous silicon and/or a dielectric which has the property of not absorbing light as much as a transparent conductive oxide (which furthermore is often composed of expensive and/or rare products). It is therefore possible, a priori, to produce cells having a higher short-circuit current and therefore a higher efficiency.

In order to produce the selective contacts on a single face, there are two possible types of junction: homojunction contact (crystalline/crystalline contact), which may for example be obtained by diffusion of dopants under the effect of a high temperature (furnace); and heterojunction contact (crystalline/amorphous contact), which may for example be obtained by deposition of doped hydrogenated amorphous silicon (a-Si:H).

Document US 2008/0035198 provides an example of a back-contact photovoltaic cell of homojunction type. Document US 2007/0137692 provides another example thereof, in which two superposed metal layers are provided for collecting respective charge carriers, which are separated from one another and which are separated from the substrate by an insulator, the contact of each metal layer with the substrate being provided by laser annealing of the metal layer at point locations.

Contacts of heterojunction type have the advantage of offering a higher open-circuit voltage (and a lower loss of efficiency at high temperature) than contacts of homojunction type. Moreover, contacts of heterojunction type make it possible to carry out both passivation and contacting.

However, the manufacture of back-contact photovoltaic cells of heterojunction type itself remains relatively difficult to implement insofar as the processes proposed to date are based on a large number of steps, for example a large number of photolithography steps, technology which is known for its precision but also for being difficult to industrialize. Similarly, the other methods available for the production of two contacts of heterojunction type on the back face (masking, lift-off) also require a large number of steps and may be not very practical to use.

For example, documents WO 03/083955, WO 2006/077343, WO 2007/085072, US 2007/0256728 and EP 1 873 840 all describe heterojunction semiconductor devices comprising a crystalline silicon substrate covered on one and the same back face with respective n-doped amorphous silicon and p-doped amorphous silicon zones, which are separated by insulating portions, and which are covered with respective metallization zones intended for collecting charge carriers.

One drawback of all these devices is that their manufacture requires two separate steps of deposition of amorphous silicon, for example using a mask in each step or else by firstly depositing one of the amorphous silicons, then by etching it before depositing the other amorphous silicon.

Consequently, there is a real need to develop a semi-conductor device suitable for operating as a photo-voltaic cell, capable of being manufactured according to a simpler process, with a reduced number of steps and which may be implemented on an industrial scale.

### SUMMARY OF THE INVENTION

The invention firstly relates to a semiconductor device comprising:
a crystalline semiconductor substrate having a front face and a back face;
a front passivation layer positioned on the front face of the substrate;
a back passivation layer positioned on the back face of the substrate;
a first metallization zone positioned on the back passivation layer and suitable for collecting electrons;
a second metallization zone suitable for collecting holes, comprising:
   a surface portion positioned on the back passivation layer; and
   an inner portion passing through the back passivation layer and forming, in the substrate, a region in which the concentration of electron acceptors is greater than the rest of the substrate.

According to one embodiment, the crystalline semiconductor substrate is an n-type or p-type doped crystalline silicon substrate.

According to one embodiment, the second metallization one comprises aluminum, and preferably the first metallization zone also comprises aluminum.

According to one embodiment, the front passivation layer comprises:
a layer of intrinsic hydrogenated amorphous silicon in contact with the substrate; and
a layer of doped hydrogenated amorphous silicon positioned on the latter, having p-type doping if the substrate is of p type, or n-type doping if the substrate is of n type; and/or the back passivation layer comprises:
   a layer of intrinsic hydrogenated amorphous silicon in contact with the substrate; and
   a layer of doped hydrogenated amorphous silicon positioned on the latter, having n-type doping.

According to one embodiment, the first metallization zone and the second metallization zone form an interdigitated structure.

According to one embodiment, the semiconductor device comprises an antireflective layer positioned on the front passivation layer, preferably comprising hydrogenated amorphous silicon nitride.

According to one embodiment, this semiconductor device is a photovoltaic cell.

Another subject of the invention is a module of photo-voltaic cells, comprising several photovoltaic cells as described above, connected in series or in parallel.

Another subject of the invention is a process for manufacturing a semiconductor device comprising:
the provision of a crystalline semiconductor substrate having a front face and a back face;
the formation of a front passivation layer on the front face of the substrate;
the formation of a back passivation layer on the back face of the substrate;
the formation of a first metallization zone on the back passivation layer, suitable for collecting electrons;
the formation of a second metallization zone, comprising:
   the formation of a surface portion of the second metallization zone on the back passivation layer, suitable for collecting holes;
   the formation of an inner portion of the second metallization zone, which passes through the back passivation layer and forms in the substrate a region having a concentration of electron acceptors greater than the rest of the substrate, by laser annealing of the surface portion of the second metallization zone.

According to one embodiment, the crystalline semiconductor substrate is an n-type or p-type doped crystalline silicon substrate.

According to one embodiment:
the formation of the front passivation layer on the front face of the substrate comprises the formation of a layer of intrinsic hydrogenated amorphous silicon in contact with the substrate; and the formation of a layer of doped hydrogenated amorphous silicon on the latter, having p-type doping if the substrate is of p-type, or n-type doping if the substrate is of n-type; and/or
the formation of the back passivation layer on the back face of the substrate comprises the formation of a layer of intrinsic hydrogenated amorphous silicon in contact with the substrate; and the formation of a layer of doped hydrogenated amorphous silicon having n-type doping on the latter.

According to one embodiment, the second metallization zone comprises aluminum, and preferably the first metallization zone also comprises aluminum.

According to one embodiment, the formation of the first metallization zone and the formation of the surface portion of the second metallization zone are carried out by lithography or evaporation through a mask or spraying through a mask or screen printing, and are preferably carried out simultaneously; and wherein the first metallization zone and the second metallization zone preferably form an interdigitated structure.

According to one embodiment, the process comprises the formation of an antireflective layer on the front passivation layer, said antireflective layer preferably comprising hydrogenated amorphous silicon nitride.

According to one embodiment, the semiconductor device is a photovoltaic cell.

Another subject of the invention is a process for manufacturing a module of photovoltaic cells, comprising the connection, in series or in parallel, of several photovoltaic cells as described above.

The present invention makes it possible to overcome the drawbacks of the prior art. It provides, more particularly, a semiconductor device suitable for operating as a photovoltaic cell, capable of being manufactured according to a simpler process, with a reduced number of steps and which can be implemented on an industrial scale.

This is accomplished owing to the development of a back-contact semiconductor device, as described above.

This semiconductor device may indeed be obtained with a single step of depositing doped amorphous silicon on the back face and a single step of depositing metallic material for collecting charge carriers on the back face.

According to certain particular embodiments, the invention also has one or preferably several of the advantageous features listed below.
The invention provides back-contact photo-voltaic cells, that is to say cells having no shading on the front face, and that have minimal ohmic losses due to the metallic contacts; moreover, the invention makes it possible to dispense with any transparent conductive oxide on the front face, which enables a higher short-circuit current and therefore a higher efficiency.
The semiconductor devices of the invention have an n contact of heterojunction type (that is to say a contact with a region of amorphous silicon), which guarantees very good passivation; and a p contact of homojunction type, which combined with the first makes it possible to resort to a greatly simplified manufacturing process without excessively degrading the overall passivation.
The use of the laser annealing technique for producing p-type contacts makes it possible to only damage the passivation layer on the back face in a very limited manner (that is to say at the p-type contacts themselves), since the heating by the laser is very localized on the surface. The passivation layer remains intact at the n-type contacts and between the n-type contacts and the p-type contacts.

### BRIEF DESCRIPTION OF THE FIGURES

FIG. 1 schematically represents one embodiment of a semiconductor device (especially a photovoltaic cell) according to the invention, during manufacture, in cross section (and as a partial view). The various layers of material are not to scale in the figure.

FIG. 2 represents this semiconductor device at the end of its manufacture, also in cross section and still as a partial view.

FIG. 3 represents a view of the back face of this semiconductor device at the end of its manufacture.

FIG. 4 represents a partial view of this device, in longitudinal cross section corresponding to the line A-A in FIG. 3.

### DESCRIPTION OF EMBODIMENTS OF THE INVENTION

The invention is now described in greater detail and nonlimitingly in the description which follows, by referring to the photovoltaic application of the invention.

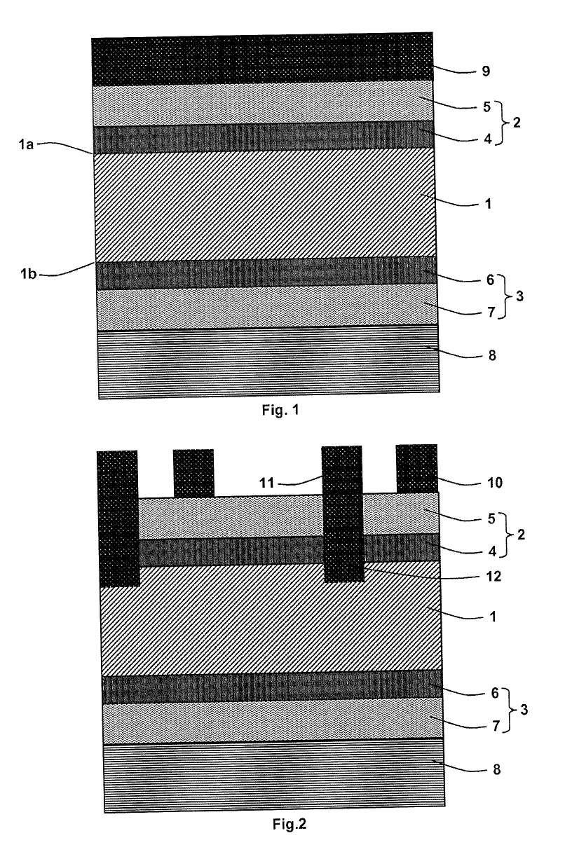

Referring to FIG. 1, a semiconductor device according to the invention may be manufactured as follows.

Firstly, a crystalline semiconductor substrate 1 having a front face 1a and a back face 1b is provided. Preferably, the crystalline semiconductor substrate 1 is a crystalline, especially monocrystalline or polycrystalline (preferably monocrystalline) silicon substrate (or wafer) in wafer form.

This substrate may be n-type or p-type doped. The use of an n-type doped substrate is particularly advantageous insofar as the lifetime of this substrate is longer. In what follows, an n-type doped substrate is taken as an example. The substrate 1 is advantageously devoid of any oxide material.

Preferably, the substrate 1 has a sufficient doping to exhibit a resistivity between around 0.1 and 1 Ω.cm.

On both sides of the substrate 1, that is to say on its front face 1a and on its back face 1b, a front passivation layer 3 and a back passivation layer 2 are applied respectively.

The front passivation layer 3 advantageously comprises a layer of amorphous intrinsic hydrogenation silicon 6 in contact with the substrate 1 and a layer of doped hydrogenated amorphous silicon 7 positioned on the latter. The layer of doped hydrogenated amorphous silicon 7 is n-doped when the substrate 1 is of n-type; or else it is p-doped when the substrate 1 is of p-type.

Symmetrically, the back passivation layer 2 advantageously comprises a layer of amorphous intrinsic hydrogenated silicon 4 in contact with the substrate 1 and a layer of doped hydrogenated amorphous silicon 5 positioned on the latter. Preferably, the layer of doped hydrogenated amorphous silicon 5 is n-doped, irrespective of the type of doping of the substrate 1.

The front passivation layer 3 and the back passivation layer 2 play a passivation role in two complementary ways: on the one hand, the presence of amorphous silicon on each face 1a, 1b of the crystalline substrate makes it possible to render the surface defects of the substrate inactive, by preventing bonds pendant to the surface, which prevents the recombination of the charge carriers before they are collected; on the other hand, the presence of the layers of doped hydrogenated amorphous silicon 5, 7 makes it possible to create a front surface field, respectively a back surface field, which also improve the collection of the charge carriers.

The deposition of the two layers of intrinsic hydrogenated amorphous silicon 4, 6 and of the two layers of doped hydrogenated amorphous silicon 5, 7 may be carried out, for example, according to the plasma-enhanced chemical vapor deposition (PECVD) technique or according to the low-pressure chemical vapor deposition (LPCVD) technique. Each of the layers may cover the whole of the surface of the substrate 1.

An antireflective layer 8 is advantageously positioned on the front passivation layer 3. This antireflective layer comprises a dielectric material, preferably hydrogenated amorphous silicon nitride. Preferably, it extends over the entire surface of the front passivation layer 3. It may be deposited, for example, according to the PECVD or LPCVD technique. The main role of the antireflective layer is to eliminate as much as possible the reflection of the light arriving on the device via the front side. The refractive index of the antireflection layer could, for example, be in the vicinity of 2. It is possible to use a textured silicon to improve the light collection.

On the back passivation layer 2, a metallic layer 9 is deposited. This may be carried out, for example, by evaporation, spraying or by electrochemical deposition. The metallic layer 9 is preferably based on aluminum. According to the embodiment represented in FIG. 1, the metallic layer 9 initially covers the entire surface of the back passivation layer 2; then, a portion of the metallic layer 9 is selectively removed (by etching or another technique) in order to obtain a first metallization zone 10 and a second metallization zone 11 separated from the first metallization zone 10.

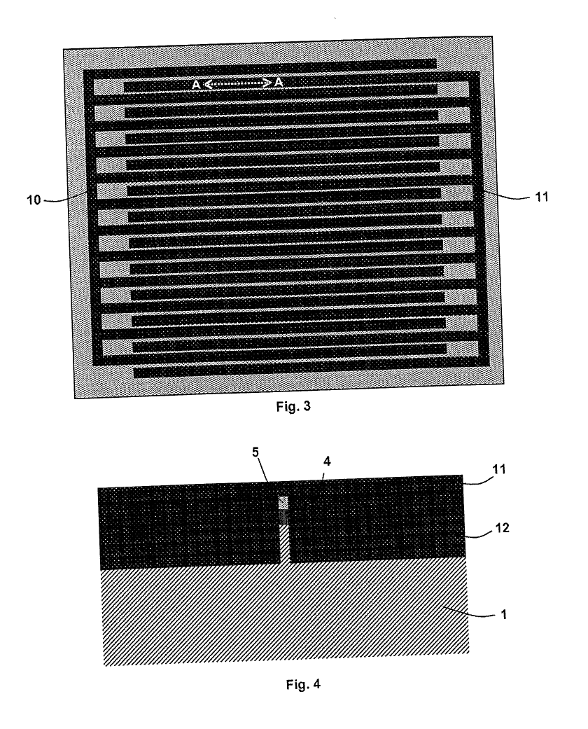

Preferably, the first metallization zone 10 and the second metallization zone 11 form an interdigitated structure as represented in FIG. 3, that is to say a structure where the two metallization zones 10, 11 form reversed and interlocked combs. The metallization zones 10, 11 are intended for collecting the respective charge carriers. An interdigitated structure enables a particularly simple electrical connection of the device.

Alternatively, it is also possible to directly apply the metallization zones 10, 11 selectively at the surface of the back passivation layer 2, so as to directly obtain the desired (for example inter-digitated) pattern. To do this, it is possible to use screen printing of metal paste, through a mask of suitable shape or else evaporation or spraying through a mask.

According to the main embodiment described above, the metallization zones 10, 11 are produced from one and the same material (preferably based on aluminum): this embodiment is indeed the simplest to implement. However, it is also possible to prepare metallization zones 10, 11 having compositions different from one another. In this case, at least the second metallization zone 11 is preferably based on aluminum.

Next a step of laser annealing (or laser firing) of the second metallization zone 11 is carried out. Laser annealing consists in applying laser pulses to the second metallization zone 11 so as to induce, over a very short time, a melting/solidification cycle over the second metallization zone 11 and also over a certain thickness of the underlying silicon. During the melting phase, the metal (especially aluminum) diffuses rapidly into the liquid silicon. During the solidification process, the silicon is again epitaxied from the underlying solid silicon; the atoms (dopants) of the metal (especially aluminum) that have diffused during the melting cycle are then placed at substitutional sites in the reconstructed crystal.

Thus, and referring to FIG. 2, at the end of the laser annealing, the second metallization zone comprises, on the one hand, a surface portion 11, positioned on the back passivation layer 3 and which essentially corresponds to the second metallization zone before laser annealing; and, on the other hand, an inner portion 12 that passes through the back passivation layer 2 and that penetrates into the substrate 1, this inner portion 12 being obtained by diffusion of the atoms (especially of aluminum) during the laser annealing.

The inner portion 12 of the second metallization zone therefore comprises a region of the substrate 1, located below the surface portion 11 of the second metallization zone, which is p+ doped (that is to say which has a high concentration of p-type dopants, especially aluminum atoms). In other words, the inner portion 12 of the second metallization zone thus forms, in the substrate 1, a region in which the concentration of electron acceptors is greater than the rest of the substrate 1, this being whether the substrate 1 is of n-type or of p-type. When the substrate 1 is of n-type, a p-n type junction is thus formed between the region of the substrate 1 modified by laser annealing and the rest of the substrate 1; and when the substrate 1 is of p-type, a p-p+ type junction is thus formed.

The extreme rapidity of the solidification front during the laser annealing favors the formation of square profiles, and makes it possible to achieve activation rates greater than those obtained with conventional techniques. According to this technique, the laser energy determines the thickness of the region of the substrate 1 thus doped. Following the laser treatment, the dopants are electrically active, the doping profile is virtually square, with very steep sides.

The following documents provide examples of the implementation of the laser annealing technique:
Laser fired back contact for silicon cells, Tucci et al., Thin solid films 516:6767-6770 (2008);
Laser fired contacts on amorphous silicon deposited by hot-wire CVD on crystalline silicon, Blanque et al., 23rd European photovoltaic solar energy conference, 1-5 Sep. 2008, Valence (Espagne), p. 1393-1396;
Bragg reflector and laser fired back contact in a-Si:H/c-Si heterostructure, Tucci et al., Materials Science and Engineering B 159-160:48-52 (2009).

Typically, a pulsed Nd-YAG laser or a pulsed UV excimer laser could be used. By way of example, use could be made of an Nd-YAG Q-switched laser at 1064 nm in TEM₀₀ mode, with a power of 300 to 900 mW and a pulse duration of 100 ms with a repeat frequency of 1 kHz.

Generally, the power of the laser and the pulse duration are adjusted as a function of the annealing depth and of the induced doping that are desired. The speed of movement of the laser and the frequency are adjusted in order to adjust the distance between the laser impacts.

When the surface portion 11 of the second metallization zone has a pattern of bands, as is the case in the context of an interdigitated structure, the distance between the laser impacts along the bands of the pattern (see FIG. 4) must be small enough in order to limit the ohmic losses and to optimize the collection of the charges.

At the end of the laser annealing:
The first metallization zone 10 remains present only on top of the back passivation layer 2 and more precisely on top of the layer of n-doped hydrogenated amorphous silicon 5. Consequently, this first metallization zone 10 ensures an n-type contact, that is to say is suitable for collecting electrons.
The second metallization zone has been converted to p-type contact, that is to say that it is suitable for collecting holes.

By way of indication, the geometry of the semiconductor device thus obtained may be the following:
Substrate 1: thickness between 150 and 300 μm.
Layers of intrinsic hydrogenated amorphous silicon 4, 6: thickness between 1 and 10 nm, especially between 3 and 5 nm.
Layers of doped hydrogenated amorphous silicon 5, 7: thickness between 5 and 30 nm, especially between 5 and 15 nm.
Antireflective layer 8: thickness between 50 and 100 nm.
First metallization zone 10 and surface portion 11 of the second metallization zone: thickness between 2 and 30 μm, especially between 2 and 10 μm.

If the two metallization zones have an interdigitated form, as is represented here, these metallization zones comprise parallel bands positioned alternately. Each band may have a typical width of 50 to 400 μm and especially from 50 to 200 μm (for example around 100 μm) and two bands may be separated by a typical distance of 50 to 200 μm (for example around 100 μm).

The length of diffusion of the charger carriers into the back passivation layer 2 is typically around 20 nm due to the presence of doped amorphous silicon. Consequently, the charge carriers may pass through the back passivation layer 2 depending on its thickness, but cannot essentially pass through it in a direction parallel to the back face la of the substrate 1. Consequently, there is practically no short circuit possible between the two respective metallization zones.

The above description relates to semiconductor devices that are generally used as photovoltaic cells. One or more of these devices may be incorporated in the form of a module of photovoltaic cells. For example, a certain number of photovoltaic cells may be connected electrically, in series and/or in parallel, in order to form the module.

The module may be manufactured in various ways. For example, it is possible to place photovoltaic cells between glass sheets, or between a sheet of glass and a sheet of transparent resin, for example made of ethylene/vinyl acetate. If all the photovoltaic cells have their front face oriented in the same direction, it is also possible to use a non-transparent (metallic, ceramic or other) sheet on the back side. It is also possible to manufacture modules that receive light on two opposite faces (see for example document U.S. Pat. No. 6,667,435 in this regard). A sealing resin may be provided in order to seal the sides of the module and protect it from atmospheric moisture. Various resin layers may also be provided in order to prevent the undesirable diffusion of sodium resulting from the sheets of glass.

The module moreover generally comprises means of static conversion at the terminals of the photovoltaic cells.

Depending on the applications, these may be direct current-alternating current (DC/AC) conversion means and/or direct current-direct current (DC/DC) conversion means. The static conversion means are suitable for transmitting the electric power provided by the photo-voltaic cells to a charge of an external application—battery, electrical network or other. These static conversion means are suitable for reducing the current transmitted and for increasing the voltage transmitted. The static conversion means may be combined with an electronic controller.

The details of the manufacture of the solar module (support elements, frame, electrical connections, encapsulation, etc.) are well known to a person skilled in the art.

1. A semiconductor device comprising:
a crystalline semiconductor substrate having a front face and a back face;
a front passivation layer positioned on the front face of the substrate;
a back passivation layer positioned on the back face of the substrate;
a first metallization zone 40)-positioned on the back passivation layer and suitable for collecting electrons;
a second metallization zone suitable for collecting holes, comprising:
a surface portion positioned on the back passivation layer; and
an inner portion passing through the back passivation layer and forming, in the substrate, a region in which the concentration of electron acceptors is greater than the rest of the substrate.

2. The semiconductor device as claimed in claim 1, wherein the crystalline semiconductor substrate is a n-type or p-type doped crystalline silicon substrate.)

3. The semiconductor device as claimed in claim 1, wherein the second metallization zone comprises aluminum, and preferably the first metallization zone also comprises aluminum.

4. The semiconductor device as claimed in claim 1, wherein the front passivation layer comprises:
a layer of intrinsic hydrogenated amorphous silicon in contact with the substrate; and
a layer of doped hydrogenated amorphous silicon positioned on the latter, having p-type doping if the substrate is of p type, or n-type doping if the substrate is of n type; and/or
the back passivation layer comprises:
a layer of intrinsic hydrogenated amorphous silicon in contact with the substrate; and
a layer of doped hydrogenated amorphous silicon positioned on the latter, having n-type doping.

5. The semiconductor device as claimed in claim 1, wherein the first metallization zone and the second metallization zone form an interdigitated structure.

6. The semiconductor device as claimed in claim 1, comprising an antireflective layer positioned on the front passivation layer, preferably comprising hydrogenated amorphous silicon nitride.

7. The semiconductor device as claimed in claim 1, wherein the semiconductor device being-is a photovoltaic cell.

8. A photovoltaic module, comprising plurality of photovoltaic cells connected in series or in parallel each of the plurality of photovoltaic cells comprising:
a crystalline semiconductor substrate having a front face and a back face;
a front passivation layer positioned on the front face of the substrate;
a back passivation layer positioned on the back face of the substrate;
a first metallization zone positioned on the back passivation layer and suitable for collecting electrons;
a second metallization zone suitable for collecting holes, the second metallization zone comprising:
a surface portion positioned on the back passivation layer; and
an inner portion passing through the back passivation layer and forming, in the substrate, a region in which the concentration of electron acceptors is greater than the rest of the substrate.

9. A process for manufacturing a semiconductor device comprising:
providing a crystalline semiconductor substrate having a front face and a back face;
forming the formation of a front passivation layer on the front face of the substrate;
forming a back passivation layer on the back face of the substrate;
forming a first metallization zone on the back passivation layer, suitable for collecting electrons;
forming a second metallization zone, comprising:
forming a surface portion of the second metallization zone on the back passivation layer, suitable for collecting holes;
forming an inner portion of the second metallization zone, which passes through the back passivation layer and forms in the substrate a region having a concentration of electron acceptors greater than the rest of the substrate, by laser annealing of the surface portion of the second metallization zone.

10. The process as claimed in claim 9, wherein the crystalline semiconductor substrate is a n-type or p-type doped crystalline silicon substrate.

11. The process as claimed in claim 9, wherein:
the formation of the front passivation layer on the front face of the substrate comprises forming a layer of intrinsic hydrogenated amorphous silicon in contact with the substrate; and
forming a layer of doped hydrogenated amorphous silicon on the latter, having p-type doping if the substrate is of p-type, or n-type doping if the substrate is of n-type; and/or
forming the back passivation layer on the back face of the substrate comprises forming a layer of intrinsic hydrogenated amorphous silicon in contact with the substrate; and forming a layer of doped hydrogenated amorphous silicon having n-type doping on the latter.

12. The process as claimed in claim 9, wherein the second metallization zone comprises aluminum, and the first metallization zone also comprises aluminum.

13. The process as claimed in claim 9, wherein forming the first metallization zone and forming the surface portion of the second metallization zone are carried out by at least one of:
a lithographic process;
an evaporation process through a mask;
spraying through a mask; or
screen printing.

14. The process as claimed in claim 9, comprising forming an antireflective layer on the front passivation layer, said antireflective layer preferably comprising hydrogenated amorphous silicon nitride.

15. The process as claimed in claim 9, wherein the semiconductor device is a photovoltaic cell.

16. A process for manufacturing a module of photovoltaic cells, comprising the connection, in series or in parallel, of several photovoltaic cells as claimed in claim 7.

17. The process of claim 13 wherein forming the first metallization zone and forming the surface portion of the second metallization zone are carried out substantially simultaneously.

18. The process of claim 17 wherein the first and second metallization zones form an interdigitated structure.
